(19) United States
(12) Patent Application Publication
(10) Pub. No.: US 2021/0289612 A1
(43) Pub. Date: Sep. 16, 2021

(54) PLASMA MEASURING APPARATUS AND PLASMA MEASURING METHOD

(71) Applicant: TOKYO ELECTRON LIMITED, Tokyo (JP)

(72) Inventor: Shinji KUBOTA, Miyagi (JP)

(73) Assignee: TOKYO ELECTRON LIMITED, Tokyo (JP)

(21) Appl. No.: 17/191,796

(22) Filed: Mar. 4, 2021

(30) Foreign Application Priority Data
Mar. 11, 2020 (JP) 2020-041976

(51) Int. Cl. H05H 1/00

(52) U.S. Cl. CPC H05H 1/0037

(57) ABSTRACT

A plasma measuring apparatus includes a chamber; a stage provided in the chamber; a plasma generation source configured to generate plasma in the chamber; a transmission window provided in the chamber and configured to transmit light; a phosphor arranged in the chamber and configured to emit light according to energy of incident electrons; a spectroscope arranged outside the chamber and configured to measure light emission from the phosphor through the transmission window; and a controller configured to measure an ion energy from measurement results by the spectroscope.

### CROSS-REFERENCE TO RELATED APPLICATION

This application is based on and claims priority from Japanese Patent Application No. 2020-041976 filed on Mar. 11, 2020 with the Japan Patent Office, the disclosure of which is incorporated herein in its entirety by reference.

### TECHNICAL FIELD

The present disclosure relates to a plasma measuring apparatus and a plasma measuring method.

### BACKGROUND

Japanese Patent Laid-Open Publication No. 2014-513390 discloses a method of measuring an ion current using a measurement substrate as a method of measuring an ion energy.

### SUMMARY

A plasma measuring apparatus according to an aspect of the present disclosure includes a chamber, a stage, a plasma generation source, a transmission window, a phosphor, a spectroscope, and a controller. The stage is provided in the chamber. The plasma generation source generates plasma in the chamber. The transmission window is provided in the chamber to transmit light. The phosphor is arranged in the chamber and emits light according to the energy of incident electrons. The spectroscope is arranged outside the chamber and measures the emission from the phosphor through the transmission window. The controller measures the ion energy from the measurement result by the spectroscope.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating an example of a plasma processing apparatus according to a first embodiment.

FIG. 2 is a schematic cross-sectional view illustrating an example of arrangement of phosphors according to an embodiment.

FIG. 3 is a diagram schematically illustrating an electrical state of the surface of a substrate according to the embodiment.

FIG. 4 is a diagram schematically illustrating a potential of a plasma processing space according to the embodiment.

FIG. 5 is a diagram illustrating an example of electron energy distribution according to the embodiment.

FIG. 6 is a diagram illustrating an example of a relationship between the potential of the substrate and the change in the emission intensity of the phosphor according to the embodiment.

FIG. 7 is a diagram illustrating an example of arrangement of phosphors according to the embodiment.

FIG. 8 is a diagram illustrating an example of arrangement of phosphors according to the embodiment.

FIG. 9 is a diagram illustrating a cross section of a transmission window according to the embodiment.

FIG. 10 is a diagram schematically illustrating the emission characteristics of a plurality of types of phosphors according to the embodiment.

FIG. 11 is a diagram illustrating an example of a relationship between the energy of incident electrons and the emission intensity of a plurality of types of phosphors according to the embodiment.

FIG. 12 is a flowchart illustrating an example of the flow of a plasma measuring method according to the first embodiment.

FIG. 13 is a schematic cross-sectional view illustrating an example of a plasma processing apparatus according to a second embodiment.

FIG. 14 is a diagram illustrating an example of electron energy distribution according to the second embodiment.

FIG. 15 is a flowchart illustrating an example of the flow of the plasma measuring method according to the second embodiment.

### DETAILED DESCRIPTION

In the following detailed description, reference is made to the accompanying drawing, which form a part thereof. The illustrative embodiments described in the detailed description, drawing, and claims are not meant to be limiting. Other embodiments may be utilized, and other changes may be made without departing from the spirit or scope of the subject matter presented here.

Hereinafter, embodiments of a plasma measuring apparatus and a plasma measuring method disclosed in the present application will be described in detail with reference to the drawings. The present embodiments do not limit the disclosed plasma measuring apparatus and plasma measuring method.

When measuring the ion energy in the plasma processing space using the measurement substrate, wiring is required to connect the measurement substrate inside the plasma processing space (inside the chamber) to the voltmeter and ammeter outside the plasma processing space (outside the chamber). In this wiring, since the radio-frequency power applied for plasma generation may leak to the outside and cause a malfunction in other systems, it is necessary to extract only the direct current through a low-pass filter. However, it is difficult to completely remove the radio-frequency current by the low-pass filter, and the radio-frequency current flows from the substrate to the GND, which may cause an error in measurement. Further, since the potential on the measurement substrate may reach several KV, it is necessary to take a withstand voltage with the GND. However, it is extremely difficult to give the wiring a high withstand voltage of several KV. Therefore, when a measurement is performed by this measuring method under high bias conditions such as those used in an actual process, dielectric breakdown may occur without having a withstand voltage of the wiring, and abnormal discharge may occur. In addition, the measurement system may be destroyed due to abnormal discharge. Therefore, it is difficult to measure the ion energy in the high power region.

Therefore, a new technique for measuring the ion energy of plasma processing is expected.

### First Embodiment

[Apparatus Configuration]

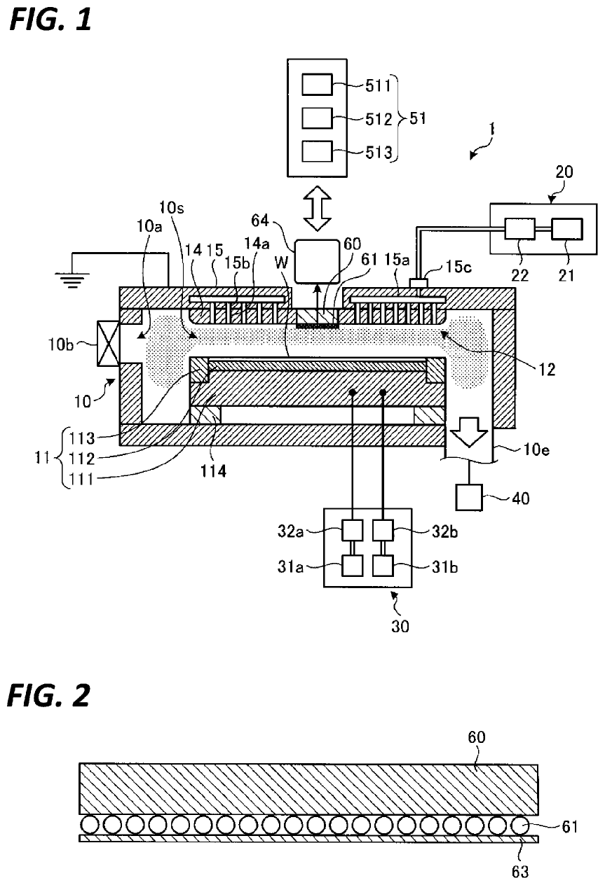

An embodiment will be described. Hereinafter, a case where the configuration of the plasma measuring apparatus of the present disclosure is applied to a plasma processing apparatus will be described as an example. FIG. 1 is a schematic cross-sectional view illustrating an example of a plasma processing apparatus 1 according to a first embodiment. The plasma processing apparatus 1 according to the first embodiment is, for example, a capacitively coupled plasma (CCP) type plasma etching apparatus including electrodes of parallel flat plates. The plasma processing apparatus 1 includes a plasma processing chamber 10, a gas supply 20, a radio-frequency (RF) power supply 30, and an exhaust system 40. Further, the plasma processing apparatus 1 includes a support portion 11 and an upper electrode shower head 12. The plasma processing apparatus 1 further includes a controller 51.

The plasma processing chamber 10 is made of a material such as aluminum, and is formed in, for example, a substantially cylindrical shape. The inner wall surface of the plasma processing chamber 10 is anodized. Further, the plasma processing chamber 10 is grounded for safety. The support portion 11 is arranged in the lower region of a plasma processing space 10s in the plasma processing chamber 10. The upper electrode shower head 12 is arranged above the support portion 11 and may function as a part of the ceiling of the plasma processing chamber 10.

The support portion 11 is configured to support a substrate W in the plasma processing space 10s. In the embodiment, the support portion 11 includes a lower electrode 111, an electrostatic chuck 112, and an edge ring 113. The electrostatic chuck 112 is configured to be arranged on the lower electrode 111 and support the substrate W on the upper surface of the electrostatic chuck 112. The edge ring 113 is arranged so as to surround the substrate W on the upper surface of a peripheral edge portion of the lower electrode 111. Further, although not illustrated, in the embodiment, the support portion 11 may include a temperature control module configured to adjust at least one of the electrostatic chuck 112 and the substrate W to a target temperature. The temperature control module may include a heater, a flow path, or a combination of these elements. A temperature control fluid such as a coolant or a heat transfer gas flows through the flow path. The support portion 11 is supported by a support member 114 provided on the bottom surface of the plasma processing chamber 10. The support portion 114 is formed of an insulating material. The plasma processing chamber 10 and the support portion 11 are insulated by the support member 114.

The upper electrode shower head 12 is supported on the upper portion of the processing container 10 via an insulating shielding member 32 (not illustrated). The upper electrode shower head 12 includes an electrode plate 14 and an electrode support 15. The lower surface of the electrode plate 14 faces the plasma processing space 10s. A plurality of gas ejection ports 14a is formed in the electrode plate 14. The electrode plate 14 is made of, for example, a material containing silicon.

The electrode support 15 is made of a conductive material such as aluminum. The electrode support 15 detachably supports the electrode plate 14 from above. The electrode support 15 is grounded for safety. The electrode support 15 may include a water-cooled structure (not illustrated). A diffusion chamber 15a is formed inside the electrode support 15. From the diffusion chamber 15a, a plurality of gas flow ports 15b communicating with the gas ejection ports 14a of the electrode plate 14 extends downward (toward the support portion 11). The electrode support 15 is provided with a gas inlet 15c that guides a processing gas to the diffusion chamber 15a, and the gas supply 20 is connected to the gas inlet 15c via a pipe.

The upper electrode shower head 12 is configured to supply one or more processing gases from the gas supply 20 to the plasma processing space 10s. In the embodiment, the upper electrode shower head 12 is configured to supply one or more processing gases from the gas inlet 15c to the plasma processing space 10s via the gas diffusion chamber 12b, the gas outlet 12c, and the gas ejection port 14a.

The gas supply 20 may include one or more gas sources 21 and one or more flow rate controllers 22. In the embodiment, the gas supply 20 is configured to supply one or more processing gases from the corresponding gas sources 21 to the gas inlet 12a via the corresponding flow rate controllers 22. Each flow rate controller 22 may include, for example, a mass flow controller or a pressure-controlled flow rate controller. Further, the gas supply 20 may include one or more flow rate modulation apparatuses that modulate or pulse the flow rate of one or more processing gases.

The RF power supply 30 is configured to supply RF power, for example, one or more RF signals, to one or more electrodes such as the lower electrode 111, the upper electrode shower head 12, or both the lower electrode 111 and the upper electrode shower head 12. As a result, plasma is generated from one or more processing gases supplied to the plasma processing space 10s. Therefore, the RF power supply 30 may function as at least a part of a plasma generator configured to generate plasma from one or more processing gases in the plasma processing chamber. In the embodiment, the RF power supply 30 includes two RF generators 31a and 31b, and two matching circuits 32a and 32b. In the embodiment, the RF power supply 30 is configured to supply a first RF signal from the first RF generator 31a to the lower electrode 111 via the first matching circuit 32a. For example, the first RF signal may have frequencies in the range of 27 MHz to 100 MHz.

In addition, in the embodiment, the RF power supply 30 is configured to supply a second RF signal from the second RF generator 31b to the lower electrode 111 via the second matching circuit 32b. For example, the second RF signal may have frequencies in the range of 400 kHz to 13.56 MHz. Instead, a direct current (DC) pulse generator may be used instead of the second RF generator 31b.

Further, although not illustrated, other embodiments may be considered in the present disclosure. For example, the RF power supply 30 may be configured to supply the first RF signal from the RF generator to the lower electrode 111, supply the second RF signal from the other RF generator to the lower electrode 111, and supply a third RF signal from yet another RF generator to the lower electrode 111. In addition, in other alternative embodiment, a DC voltage may be applied to the upper electrode shower head 12.

Further, in various embodiments, the amplitude of one or more RF signals (i.e., the first RF signal, the second RF signal, etc.) may be pulsed or modulated. Amplitude modulation may include pulsing the amplitude of the RF signal between the on and off states, or between two or more different on states.

The exhaust system 40 may be connected to, for example, an exhaust port 10e provided at the bottom of the plasma processing chamber 10. The exhaust system 40 may include a pressure valve and a vacuum pump. The vacuum pump may include a turbo molecular pump, a roughing pump, or a combination of these pumps.

The side wall of the plasma processing chamber 10 is provided with an opening 10a for carrying in or out the substrate W. The opening 10a may be opened and closed by a gate valve 10b.

Further, a transmission window 60 is provided above the plasma processing chamber 10 to transmit light. In the present embodiment, the transmission window 60 is provided in the center of the upper electrode shower head 12 that functions as the ceiling of the plasma processing chamber 10.

Further, a phosphor 61 that emits light according to the energy of incident electrons is provided in the plasma processing chamber 10. The phosphor 61 is arranged at the upper portion in the plasma processing chamber 10. In the present embodiment, the phosphor 61 is arranged on the surface of the transmission window 60 facing the support portion 11.

FIG. 2 is a schematic cross-sectional view illustrating an example of arrangement of phosphors 61 according to the embodiment. In FIG. 2, the upper side is the upper electrode shower head 12 side, and the lower side is the support portion 11 side. FIG. 2 illustrates the transmission window 60. The transmission window 60 is made of, for example, a quartz substrate and has a transmittance of transmitting light (visible light). Phosphors 61 are arranged on the entire surface of the lower surface of the transmission window 60. A thin film 63 made of metal is formed on the surface of the phosphor 61. The thin film 63 is formed of, for example, aluminum. The thin film 63 is formed thin enough to allow electrons to pass through. For example, when the thin film 63 is formed of aluminum, the thin film 63 has a thickness to about 1 to 10 nm so that electrons are transmitted. The phosphor 61 is formed to have a thickness of, for example, several tens of μm.

FIG. 1 is referred back to. A spectroscope 64 is arranged on the upper surface of the transmission window 60. The spectroscope 64 measures the light emission from the phosphor 61 through the transmission window 60. The spectroscope 64 outputs the measured measurement data to the controller 51.

The controller 51 processes computer-executable instructions that cause the plasma processing apparatus 1 to perform the various steps described in the present disclosure. The controller 51 may be configured to control each element of the plasma processing apparatus 1 to perform the various steps described herein. The controller 51 may include, for example, a computer. The computer may include, for example, a processing unit (CPU: Central Processing Unit) 511, a storage unit 512, and a communication interface 513. The processing unit 511 may be configured to perform various control operations based on the program stored in the storage unit 512. The storage unit 512 may include a random access memory (RAM), a read only memory (ROM), a hard disk drive (HDD), a solid state drive (SSD), or a combination of these elements. The communication interface 513 may communicate with another apparatus such as another plasma processing apparatus 1 via a communication line such as a local area network (LAN).

Next, brief descriptions will be made on the flow of operation performed when measuring the ion energy during plasma processing with respect to the substrate W by the plasma processing apparatus 1 according to the first embodiment. The substrate W held on a transfer arm is carried into the plasma processing chamber 10 from the gate valve 10b, and the substrate W to be plasma-processed is placed on the electrostatic chuck 112.

The gas supply 20 introduces the processing gas used for plasma generation into the plasma processing chamber 10 at a predetermined flow rate and flow rate ratio. Further, the exhaust system 40 reduces the pressure in the plasma processing chamber 10 to a set value. The RF power supply 30 also supplies radio-frequency power of the first RF signal and the second RF signal of predetermined power to the lower electrode 111 from the two RF generators 31a and 31b, respectively. The processing gas introduced from the upper electrode shower head 12 into the plasma processing space 10s in a shower shape is turned into plasma by the radio-frequency power of the first RF signal of the RF power supply 30. As a result, plasma is generated in the plasma processing space 10s. The plasma contains radicals and ions of the processing gas. Radicals in the plasma are supplied onto the substrate W by diffusion. The positive ions in the plasma are drawn toward the substrate W by the voltage of the radio-frequency power generated by the radio-frequency power of the second RF signal.

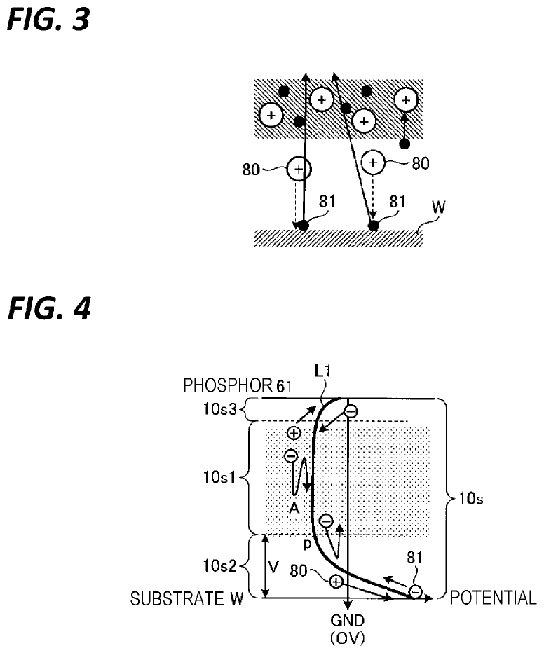

FIG. 3 is a diagram schematically illustrating an electrical state of the surface of the substrate W according to the embodiment. When the first RF signal and the second RF signal are applied to the lower electrode, a plasma sheath is formed in the vicinity of the substrate W. The substrate W has a negative potential with respect to the plasma due to self-bias. The magnitude of this negative potential depends on the power of the first RF signal and the second RF signal applied to the lower electrode. The negative self-bias applied to the substrate W creates an electric field in the sheath, and this electric field accelerates positive ions in the substrate direction. The substrate W is etched by the incidence of accelerated positive ions 80. Further, the substrate W emits secondary electrons 81 when the ions 80 are incident on the substrate W. Since the secondary electrons 81 have a negative charge, the electrons are accelerated in the direction opposite to that of the ions by the electric field in the sheath. Acceleration is made to the upper electrode shower head 12, which becomes the upper side, by the voltage of the radio-frequency power generated by the radio-frequency power of the second RF signal. A part of the secondary electrons 81 accelerated toward the upper electrode shower head 12 passes through the thin film 63 and is incident on the phosphor 61.

FIG. 4 is a diagram schematically illustrating a potential of the plasma processing space 10s according to the embodiment. In FIG. 3, the upper side is the phosphor 61 and the lower side is the substrate W, and the position of the plasma processing space 10s in the vertical direction is illustrated. A plasma region 10s1 is generated in the plasma processing space 10s. Further, in the plasma processing space 10s, a sheath region 10s2 is formed between the plasma region 10s1 and the substrate W, and a sheath region 10s3 is formed between the phosphor 61 and the plasma region 10s1. In addition, in FIG. 3, the potential of the electrode support 15 that is grounded for safety of the upper electrode shower head 12 is defined as GND, and the potential is illustrated in the left and right direction, and the potential at each position in the vertical direction of the plasma processing space 10s is indicated by the line L1. The plasma region 10s1 has, for example, a potential of about +20 to 30 V (corresponding to the plasma potential).

In the sheath region 10s2, a sheath voltage V is generated by the radio-frequency power of the second RF signal applied to the plasma region 10s1 and the lower electrode 111. The sheath voltage V is, for example, −500 to −2000 V. The positive ions in the plasma are accelerated toward the substrate W by the electric field caused by the sheath voltage V and collide with the surface of the substrate W. The substrate W emits secondary electrons 81 when high-energy ions collide with the surface. The secondary electrons 81 are accelerated in the direction of the upper electrode shower head 12 on the side opposite to the substrate W by the electric field caused by the sheath voltage V. The accelerated secondary electrons 81 are called hot electrons. A part of electrons of the secondary electrons 81 is incident on the phosphor 61 without colliding with the gas in the plasma. Although the electrons are decelerated by the potential difference applied to the sheath region 10s3 between the phosphor 61 and the plasma region 10s1, the potential difference in the sheath region 10s3 is about 20 to 30 V. Since the bias applied to the substrate W is much larger than the potential difference in the sheath region 10s3 (500 V or more), the loss of electron energy due to the sheath region 10s3 is almost negligible. Therefore, the energy of the electrons colliding with the phosphor 61 is substantially equal to the energy of the electrons due to the potential difference applied in the vicinity of the substrate.

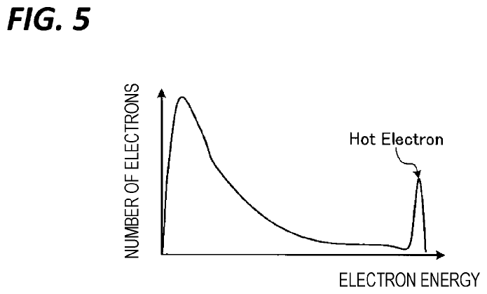

FIG. 5 is a diagram illustrating an example of electron energy distribution according to the embodiment. FIG. 5 illustrates the energy distribution of the electrons incident on the phosphor 61. The horizontal axis of FIG. 5 indicates the energy of electrons. The vertical axis of FIG. 5 indicates the energy of incident electrons. The energy distribution of electrons incident on the phosphor 61 tends to decrease as the energy increases, but a peak is generated by the secondary electrons 81 (hot electrons).

As for the phosphor 61, a phosphor that emits light by receiving the energy of electrons is used. The amount of energy required to emit light depends on the type of phosphor, but in the present disclosure, a phosphor that emits light by receiving energy of about 500 eV to 40 KeV is used. The energy of electrons existing in a normal glow discharge has a peak at several eV, and even high-energy electrons rarely have several tens of eV. Meanwhile, hot electrons have an energy of about 500 eV to several tens of KeV. Therefore, the phosphor emits light only with hot electrons having accelerated energy in the vicinity of the substrate W without reacting with electrons having normal energy.

The emission wavelength and emission intensity of the phosphor 61 change depending on the energy and the number of electrons of the secondary electrons 81. As illustrated in FIG. 2, a thin film 63 is formed on the plasma processing space 10s of the phosphor 61. Therefore, the light emission of plasma is shielded by the thin film 63. Therefore, only the light emitted by the phosphor 61 is incident on the spectroscope 64 through the transmission window 60.

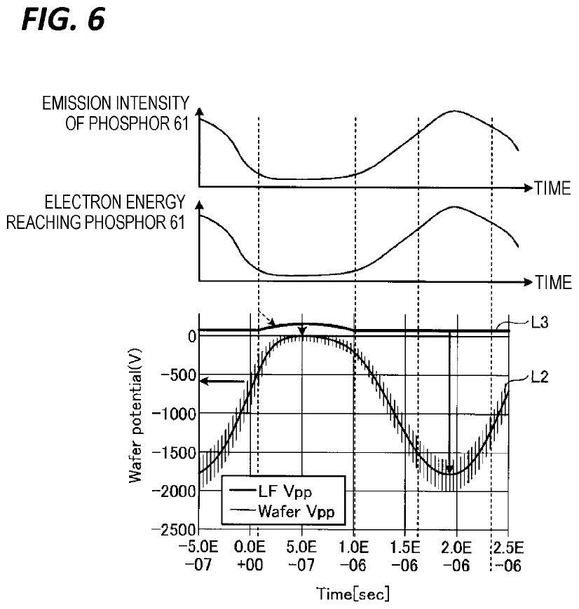

FIG. 6 is a diagram illustrating an example of a relationship between the potential of the substrate W and the change in the emission intensity of the phosphor 61 according to the embodiment. FIG. 6 illustrates a case where two radio-frequency powers of a first RF signal and a second RF signal are supplied from the RF generators 31a and 31b to the lower electrode 111. The first RF signal is, for example, 40 MHz. The second RF signal is, for example, 400 kHz. The potential of the substrate W changes to a waveform L2 on which two radio-frequency powers of the first RF signal and the second RF signal are superimposed. FIG. 6 illustrates a waveform L2 corresponding to approximately one cycle of the second RF signal. The waveform L2 vibrates finely due to the superposition of the radio-frequency power of the first RF signal. Further, FIG. 6 illustrates a line L3 indicating the potential of the plasma region 10s1. The potential difference between the line L3 and the waveform L2 corresponds to the sheath voltage V. The sheath voltage V fluctuates greatly with the period of the second RF signal. As the sheath voltage V becomes larger, the energy of the secondary electrons 81 reaching the phosphor 61 becomes larger. Therefore, the energy of the secondary electrons 81 fluctuates greatly in the same cycle as the fluctuation cycle of the sheath voltage V. The phosphor 61 emits light according to the energy of the incident electrons. Therefore, the emission intensity of the phosphor 61 fluctuates greatly in a cycle similar to the cycle of fluctuation of the sheath voltage V. Therefore, by measuring the emission intensity of the phosphor 61, it is possible to observe the time change of the ion energy accelerated toward the substrate W, which fluctuates according to the frequency (frequency at the low frequency side) of the second RF signal.

The phosphor 61 may be a material that emits light according to the energy of incident electrons. Examples of the phosphor 61 include Zn₃(PO₄)₂:Mn, Zn₂SiO₄:Mn, ZnS:Ag, ZnCdS:Ag, ZnS:Au, ZnS:Cu, ZnS:Al, YVO₄:Eu, Y₂O₃:Eu, and Y₂O₂S:Eu. For the materials represented as phosphors, the left side of “:” indicates the main material of the phosphor, and the right side of “:” indicates, for example, a small amount of material added at 1% or less. For example, ZnS:Ag is mainly made of ZnS, and Ag is added in an amount of 1% or less. The phosphor 61 is preferably a material that emits light at the energy at which the energy of the secondary electrons 81 is maximized. As for the phosphor 61, a phosphor having a short afterglow time may be used. Examples of the phosphor having a short afterglow time include a high-speed phosphor (J13550-09D) manufactured by Hamamatsu Photonics.

The spectroscope 64 measures the wavelength and emission intensity of the light emitted by the phosphor 61 through the transmission window 60. The spectroscope 64 outputs measurement data of the measured wavelength and emission intensity to the controller 51.

The controller 51 measures the ion energy from the measurement result of the spectroscope 64. For example, the controller 51 indirectly measures the ion energy by measuring the energy of the electrons incident on the phosphor 61 from the measurement data input from the spectroscope 64. For example, the controller 51 stores, in the storage unit 512, data obtained for the correspondence between the wavelength and emission intensity of the phosphor 61 and the energy of electrons. The controller 51 measures the energy of the electrons incident on the phosphor 61 from the measurement data based on the data stored in the storage unit 512. For example, the controller 51 stores, in the storage unit 512, data acquired by obtaining the correspondence between the emission intensity and the electron energy for a specific wavelength in which the emission intensity of the phosphor 61 changes according to the electron energy. The controller 51 obtains the emission intensity of a specific wavelength from the input measurement data. The controller 51 obtains the energy of electrons corresponding to the obtained emission intensity from the data stored in the storage unit 512. The controller 51 measures the ion energy from the obtained electron energy. As illustrated in FIG. 4, the secondary electrons 81 are accelerated by an electric field caused by the sheath voltage near the substrate. Therefore, the electron energy of the secondary electrons 81 of the hot electrons is related to the sheath voltage in the vicinity of the substrate, and the sheath voltage in the vicinity of the substrate may be measured from the electron energy. Also, the positive ions in the plasma are accelerated by the sheath voltage. For this reason, the ion energy of ions is related to the sheath voltage in the vicinity of the substrate and is determined by the sheath voltage. Therefore, the sheath voltage and ion energy in the vicinity of the substrate may be measured by obtaining the electron energy. For example, the controller 51 stores, in the storage unit 512, the data acquired by obtaining the correspondence between the electron energy and the ion energy. The controller 51 measures the ion energy from the obtained electron energy based on the data stored in the storage unit 512. Further, the controller 51 may store data for obtaining the correspondence between the emission intensity and the sheath voltage or ion energy, and may obtain the sheath voltage or ion energy corresponding to light emission intensity from the stored data.

Here, in the manufacture of semiconductor devices, the aspect ratio of the formed pattern is increasing. For example, in the manufacture of 3D NAND, a contact hole etching with a high aspect ratio is required. The contact hole etching with a high aspect ratio requires high ion energy. The ion energy of ions has a great influence on the shape of the process. In order to measure the ion energy in the plasma, there is a method of directly measuring the potential using a measurement substrate, for example, as in Japanese Patent Laid-Open Publication No. 2014-513390. However, there is no wiring on the substrate W that is a target of the actual plasma processing. Therefore, the ion energy measured by the measurement substrate having wiring may be different from the ion energy measured by the substrate W having no wiring. Further, since the measurement is performed using the measurement substrate, the ion energy on the substrate W, which is the target of the actual plasma processing, may not be measured in real time. Also, when the potential of the measurement substrate reaches a high voltage of −1000 V or more, a short circuit or abnormal discharge may occur, which makes it difficult to measure the ion energy while dragging the wiring from the measurement substrate.

Meanwhile, in the plasma processing apparatus 1 according to the embodiment, by installing the phosphor 61 in the plasma processing chamber 10 and measuring the emission intensity of the light emitted when high-energy electrons collide with the phosphor 61, the ion energy on the substrate W to be plasma-processed may be measured. Further, the plasma processing apparatus 1 according to the embodiment may measure the ion energy on the substrate W, which is the target of the actual plasma processing, in real time. In addition, the plasma processing apparatus 1 according to the embodiment may measure the ion energy even when the potential of the substrate W reaches a high voltage of −1000 V or more.

A plurality of types of phosphors 61 that emits light at different wavelengths due to the incidence of electrons of different energies may be arranged in the transmission window 60. In this case, adjacent phosphors 61 may be arranged so as to be of different types.

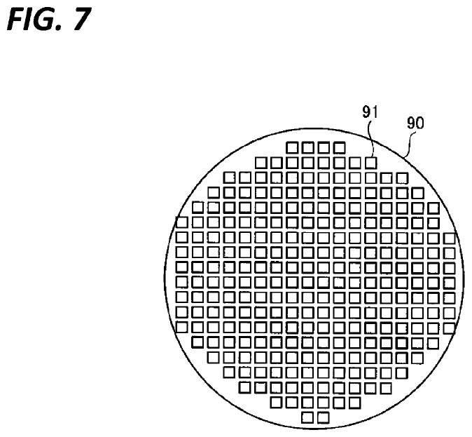

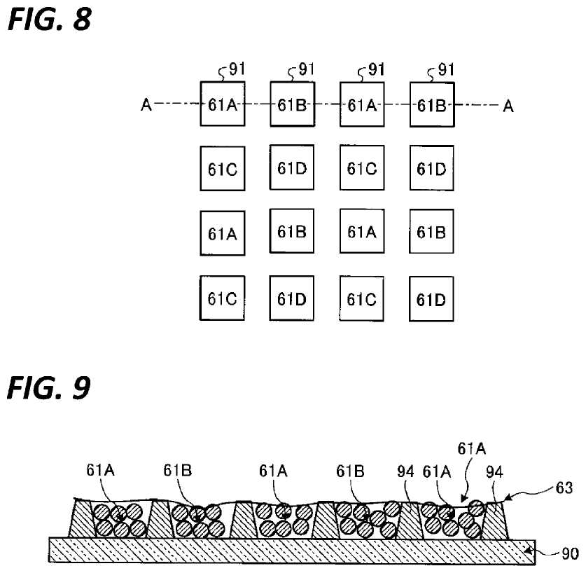

FIG. 7 is a diagram illustrating an example of arrangement of phosphors 61 according to the embodiment. In FIG. 7, regions 91 are formed in a grid pattern on a glass substrate 90 serving as the transmission window 60. Any one of the plurality of types of phosphors 61 is arranged in each region 91. At this time, the adjacent phosphors 61 are arranged so as to be of different types. FIG. 8 is a diagram illustrating an example of arrangement of phosphors 61 according to the embodiment. In FIG. 8, four types of phosphors 61A to 61D are arranged in each region 91. In FIG. 8, the phosphors 61A and 61B and the phosphors 61C and 61D are arranged alternately in each row, and the phosphors 61A to 61D are arranged in the 2×2 region 91.

FIG. 9 is a diagram illustrating a cross section of the transmission window 60 according to the embodiment. FIG. 9 is a cross-sectional view taken along line A-A in FIG. 8. In the glass substrate 90 serving as the transmission window 60, ribs 94 are formed at regular intervals and are partitioned into regions 91, and the phosphors 61A and 61B are alternately arranged in each region 91. A thin film 63 is formed on the surfaces of the phosphors 61A and 61B.

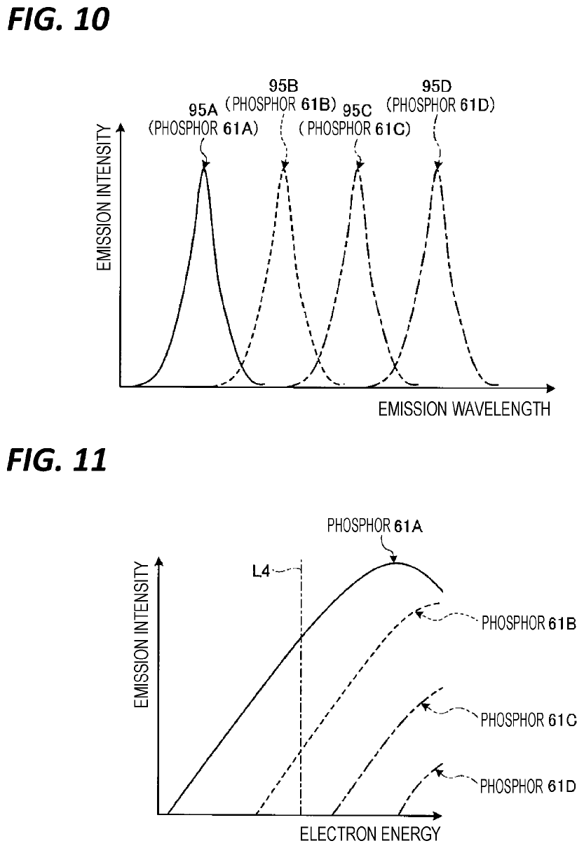

The phosphors 61A to 61D emit light at different wavelengths due to the incidence of electrons of different energies. FIG. 10 is a diagram schematically illustrating the emission characteristics of a plurality of types of phosphors 61 according to the embodiment. In FIG. 10, waveforms 95A to 95D representing the emission wavelengths and emission altitudes of the phosphors 61A to 61D are illustrated. It is assumed that the phosphor 61A emits light with the lowest electron energy among the phosphors 61A to 61D, and the peak of the emission wavelength is the lowest as illustrated in the waveform 95A. It is assumed that the phosphor 61B emits light with the second lowest electron energy among the phosphors 61A to 61D, and the peak of the emission wavelength is the second lowest as illustrated in the waveform 95B. It is assumed that the phosphor 61C emits light with the third lowest electron energy among the phosphors 61A to 61D, and the peak of the emission wavelength is the third lowest as illustrated in the waveform 95C. It is assumed that the phosphor 61D emits light with the highest electron energy among the phosphors 61A to 61D, and the peak of the emission wavelength is the highest as illustrated in the waveform 95D.

When such a plurality of types of phosphors 61A to 61D is arranged in the transmission window 60, the phosphors 61A to 61D emit light according to the energy of the incident electrons. FIG. 11 is a diagram illustrating an example of a relationship between the energy of incident electrons and the emission intensity of a plurality of types of phosphors 61A to 61D according to the embodiment. As the electron energy becomes higher, the phosphors 61A to 61D emit light in order. Therefore, the ion energy may be measured from the emission intensity of each of the phosphors 61A to 61D. For example, when the emission intensity of each of the phosphors 61A to 61D is illustrated in the line L4, the electron energy may be measured as an intermediate energy between the energy emitted by the phosphor 61B and the energy emitted by the phosphor 61C. For example, the spectroscope 64 measures the emission intensity of the wavelength at which the emission wavelength of each of the phosphors 61A to 61D peaks. The controller 51 stores, in the storage unit 512, data acquired by obtaining the correspondence with the electron energy for each combination of emission intensities of wavelengths at which the emission wavelengths of the phosphors 61A to 61D peak. The controller 51 obtains the emission intensity of the wavelength at which the emission wavelengths of the phosphors 61A to 61D peak from the measurement data input from the spectroscope 64. The controller 51 obtains the electron energy corresponding to the obtained emission intensity of the phosphors 61A to 61D from the data stored in the storage unit 512. By obtaining the electron energy in this way, the ion energy may be measured. The controller 51 may store, in the storage unit 512, data acquired by obtaining the correspondence between the sheath voltage and the ion energy for each combination of the emission intensities of the wavelengths at which the emission wavelengths of the phosphors 61A to 61D peak, and obtain the sheath voltage and ion energy corresponding to the emission intensity of the phosphors 61A to 61D from the stored data.

The plasma processing apparatus 1 according to the embodiment may measure the ion energy of plasma processing by arranging a plurality of types of phosphors 61A to 61D in this way and measuring the emission intensity of each of the phosphors 61A to 61D.

[Flow of Plasma Measurement]

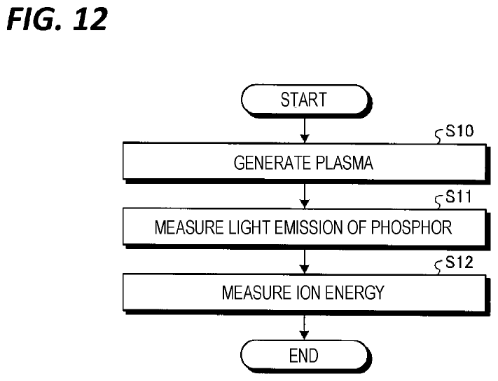

Next, the flow of the plasma measuring method performed by the plasma processing apparatus 1 according to the first embodiment will be described. FIG. 12 is a flowchart illustrating an example of the flow of the plasma measuring method according to the first embodiment.

The controller 51 controls each element of the plasma processing apparatus 1 to generate plasma in the plasma processing chamber 10 (step S10). For example, the controller 51 controls the gas supply 20 to introduce the processing gas used for plasma generation into the plasma processing chamber 10 at a predetermined flow rate and flow rate ratio. Further, the controller 51 controls the exhaust system 40 to reduce the pressure in the plasma processing chamber 10 to a set value. In addition, the controller 51 controls the RF power supply 30 to supply radio-frequency powers of the first RF signal and the second RF signal of predetermined power to the lower electrode 111 from the two RF generators 31a and 31b, respectively. As a result, plasma is generated in the plasma processing space 10s.

The controller 51 controls the spectroscope 64, and the spectroscope 64 measures the light emission from the phosphor 61 through the transmission window 60 (step S11). The spectroscope 64 outputs measurement data of the measured wavelength and emission intensity to the controller 51.

The controller 51 measures the ion energy from the measurement data input from the spectroscope 64 (step S12), and ends the process.

As described above, the plasma processing apparatus 1 according to the embodiment includes a plasma processing chamber 10, a support portion 11 (stage), an RF power supply 30 (plasma generation source), a transmission window 60, a phosphor 61, a spectroscope 64, and a controller 51. The support portion 11 is provided in the plasma processing chamber 10. The RF power supply 30 generates plasma in the plasma processing chamber 10. The transmission window 60 is provided in the plasma processing chamber 10 and transmits light. The phosphor 61 is arranged in the plasma processing chamber 10 and emits light according to the energy of incident electrons. The spectroscope 64 is arranged outside the plasma processing chamber 10 and measures the light emission from the phosphor 61 through the transmission window 60. The controller 51 measures the ion energy from the measurement result of the spectroscope 64. As a result, the plasma processing apparatus 1 may measure the ion energy of the plasma processing.

Further, the phosphor 61 is arranged in the upper portion in the plasma processing chamber 10. As a result, since hot electrons are incident on the phosphor 61, the electron energy may be measured from the emission intensity of the phosphor 61, and the ion energy may be measured from the electron energy.

Further, in the phosphor 61, a plurality of types of phosphors 61A to 61D is arranged to emit light at different wavelengths due to the incidence of electrons of different energies. The phosphors 61A to 61D are arranged so that the adjacent phosphors 61A to 61D are different types of phosphors 61A to 61D. As a result, the plasma processing apparatus 1 may measure a wide range of ion energy.

Further, the plasma processing apparatus 1 further includes an upper electrode shower head 12 facing the support portion 11 (stage). The transmission window 60 is provided in the center of the upper electrode shower head 12. The phosphor 61 is arranged on the surface of the transmission window 60 facing the support portion 11. As a result, the plasma processing apparatus 1 may measure the ion energy at the center of the upper electrode shower head 12.

Further, the phosphor 61 is any of Zn₃(PO₄)₂:Mn, Zn₂SiO₄:Mn, ZnS:Ag, ZnCdS:Ag, ZnS:Au, ZnS:Cu, ZnS:Al, YVO₄:Eu, Y₂O₃:Eu, and Y₂O₂S:Eu. As a result, the plasma processing apparatus 1 may accurately measure the ion energy.

Further, the phosphor 61 is covered with a thin film 63. As a result, the plasma processing apparatus 1 may measure only the light emission of the phosphor 61 with the spectroscope 64, so that the ion energy may be measured accurately.

### Second Embodiment

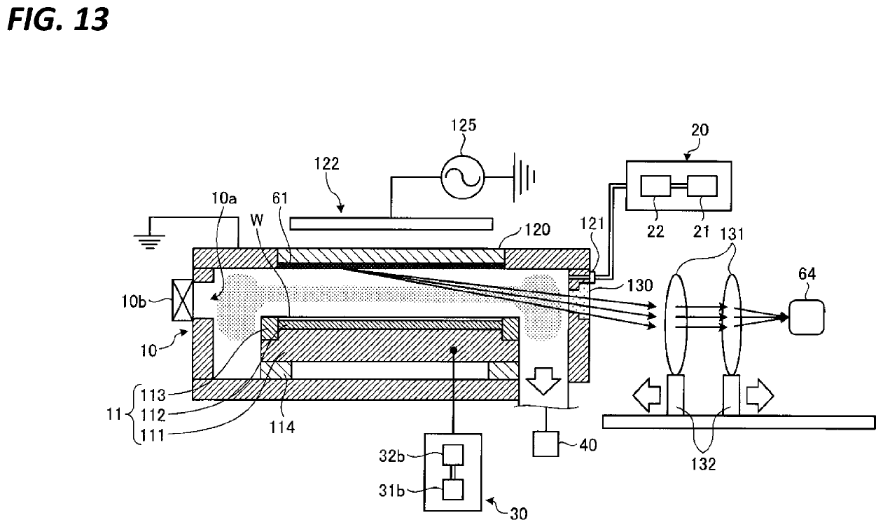

Next, a second embodiment will be described. FIG. 13 is a schematic cross-sectional view illustrating an example of the plasma processing apparatus 1 according to the second embodiment. The plasma processing apparatus 10 according to the second embodiment has substantially the same configuration as the plasma processing apparatus 10 according to the first embodiment. Thus, the same portions are denoted by the same reference numerals, descriptions thereof will be omitted, and different portions will be mainly described. The plasma processing apparatus 1 according to the second embodiment is an inductively-coupled plasma (ICP) type plasma etching apparatus.

The plasma processing chamber 10 is provided at the ceiling so that a plate-shaped dielectric 120 made of, for example, quartz glass or ceramic faces the support portion 11. For example, a circular opening is formed in the ceiling of the plasma processing chamber 10 in a range facing the support portion 11. The dielectric 120 is formed, for example, in a disk shape and is airtightly attached so as to close the opening of the plasma processing chamber 10.

A gas supply 20 is connected to the plasma processing chamber 10 to supply various gases used for processing the substrate W. A gas inlet 121 is formed on the side wall of the plasma processing chamber 10. The gas supply 20 is connected to the gas inlet 121. The gas supply 20 supplies one or more processing gases to the plasma processing space 10s. In FIG. 13, a case where the gas supply 20 is configured to supply gas from the side wall of the plasma processing chamber 10 is taken as an example, but the case is not necessarily limited to this. For example, the gas may be supplied from the ceiling of the plasma processing chamber 10.

At the ceiling of the plasma processing chamber 10, a flat radio-frequency antenna 122 is arranged on the upper surface (outer surface) of the dielectric 120. The radio-frequency antenna 122 is provided with a spiral coil-shaped antenna element made of a conductor such as, for example, copper, aluminum, or stainless steel. An RF power supply 125 is connected to the radio-frequency antenna 122. The RF power supply 125 supplies radio-frequency power of a predetermined frequency (e.g., 40 MHz) for generating plasma to the antenna element of the radio-frequency antenna 122. Further, the radio-frequency output from the RF power supply 125 is not limited to the frequencies described above. For example, various frequencies such as 13.56 MHz, 27 MHz, 40 MHz, and 60 MHz may be used.

Further, a phosphor 61 that emits light according to the energy of incident electrons is provided in the plasma processing chamber 10. The phosphor 61 is arranged at the upper portion in the plasma processing chamber 10. In the present embodiment, the phosphor 61 is arranged on the surface of the transmission window 120 facing the support portion 11.

Further, a transmission window 130 that transmits light is provided on the side surface of the plasma processing chamber 10. In the present embodiment, the transmission window 130 is provided on the side surface of the plasma processing chamber 10 on the opposite side of the opening 10a. The transmission window 130 is made of, for example, a quartz substrate and has a transmittance of transmitting light (visible light).

A spectroscope 64 is arranged outside the transmission window 130 of the plasma processing chamber 10. A plurality of lenses 131 is provided between the spectroscope 64 and the transmission window 130. The plurality of lenses 131 are arranged so as to focus on a part of the region in which the phosphor 61 is arranged. The plurality of lenses 131 are movable by a drive mechanism 132. The drive mechanism 132 includes an actuator such as a motor and a power transmission component such as a gear and a rod, and moves the plurality of lenses 131 under the control of the controller 51. By moving the plurality of lenses 131 by the drive mechanism 132, the position of the focal point may be moved within the region where the phosphor 61 is arranged. Further, the drive mechanism 132 may drive both the lens 131 and the spectroscope 64 so that the position of the focal point moves within the region where the phosphor 61 is arranged, or may drive only the spectroscope 64.

The spectroscope 64 measures the wavelength and emission intensity of the light emitted by the phosphor 61 in the region focused by the plurality of lenses 131. The spectroscope 64 moves a plurality of lenses 131 by the drive mechanism 132 to move the position of the focal point in the region where the phosphor 61 is arranged, thereby measuring the light emission of the phosphor 61 in the region where the phosphor 61 is arranged. The spectroscope 64 outputs measurement data of the measured wavelength and emission intensity to the controller 51.

Next, brief descriptions will be made on the flow of operation performed when measuring the ion energy during plasma processing with respect to the substrate W by the plasma processing apparatus 1 according to the second embodiment. When measuring the ion energy, the substrate W held on the transfer arm is carried into the plasma processing chamber 10 from a gate valve (not illustrated), and the substrate W to be plasma-processed is placed on the electrostatic chuck 112.

The gas supply 20 introduces the processing gas used for plasma generation into the plasma processing chamber 10 at a predetermined flow rate and flow rate ratio. Further, the exhaust system 40 reduces the pressure in the plasma processing chamber 10 to a set value. Also, the RF power supply 125 supplies the radio-frequency of a predetermined power to the radio-frequency antenna 122. When the radio-frequency is supplied to the radio-frequency antenna 122 from the RF power supply 125, an induced magnetic field is formed in the plasma processing chamber 10. The formed induced magnetic field excites the processing gas introduced into the plasma processing chamber 10, and plasma is generated on the substrate W. The RF power supply 30 supplies radio-frequency power of the second RF signal of predetermined power to the lower electrode 111 from the RF generator 31b. The positive ions in the generated plasma are drawn toward the substrate W by the voltage of the radio-frequency power generated by the radio-frequency power of the second RF signal.

The substrate W is etched by the incidence of the drawn positive ions. Further, the substrate W emits secondary electrons 81 when the ions are incident. Since the secondary electrons have a negative charge, the electrons are drawn to the upper dielectric 120 by the voltage of the radio-frequency power generated by the radio-frequency power of the second RF signal. The secondary electrons 81 drawn toward the dielectric 120 are incident on the phosphor 61.

The controller 51 moves a plurality of lenses 131 by the drive mechanism 132 to change the position of the focal point in the region where the phosphor 61 is arranged, comprehensively scan the region where the phosphor 61 is arranged, and measure the light emission of the phosphor 61 by the spectroscope 64. The spectroscope 64 outputs measurement data for each moved position to the controller 51. The controller 51 measures the energy of the electrons incident on the phosphor 61 from the measurement data input from the spectroscope 64. For example, the controller 51 obtains the energy of the electrons incident on the phosphor 61 for each portion in the region where the phosphor 61 is arranged from the measurement data. The controller 51 measures the ion energy from the obtained electron energy. For example, the controller 51 measures the ion energy for each portion in the region where the phosphor 61 is arranged from the electron energy for each portion in the region where the phosphor 61 is arranged. Thus, the energy distribution may be measured. Further, the controller 51 may store data for obtaining the correspondence between the emission intensity and the sheath voltage or ion energy, and may obtain the sheath voltage or ion energy corresponding to the emission intensity from the stored data.

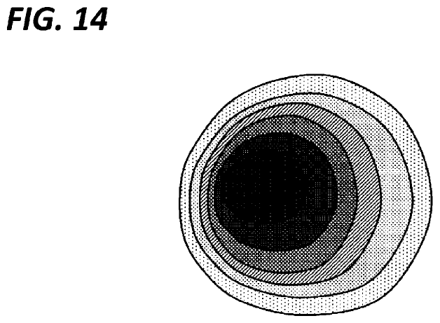

FIG. 14 is a diagram illustrating an example of electron energy distribution according to the second embodiment. In FIG. 14, the energy distribution of electrons is illustrated in a darker pattern in the region where the energy is higher. As described above, the plasma processing apparatus 1 according to the second embodiment may measure the in-plane distribution of electron energy in the plasma processing space 10s.

Similar to the first embodiment, in the plasma processing apparatus 1 according to the second embodiment, a plurality of types of phosphors 61 that emits light at different wavelengths due to the incidence of electrons of different energies may be arranged on the surface of the dielectric 120 facing the support portion 11. In this case, the adjacent phosphors 61 may be arranged so as to be of different types.

Further, in the plasma processing apparatus 1 according to the second embodiment, not only the light emitted by the phosphor 61 but also the light emitted by the plasma is measured by the spectroscope 64. Therefore, the plasma processing apparatus 1 according to the second embodiment may be configured as follows.

The plasma processing apparatus 1 according to the second embodiment is configured so that the phosphor 61 is detachable from the inside of the plasma processing chamber 1. For example, the plasma processing apparatus 1 may replace the dielectric 120 of the plasma processing chamber 10 with the dielectric 120 in which the phosphor 61 is arranged and the dielectric 120 in which the phosphor 61 is not arranged.

The plasma processing apparatus 1 generates plasma in a state where the dielectric 120 in which the phosphor 61 is not arranged is attached to the plasma processing chamber 10, and measures the emission of plasma in a state where the phosphor 61 is not arranged by the spectroscope 64. Next, the plasma processing apparatus 1 is replaced with the dielectric 120 in which the phosphor 61 is arranged. Then, the plasma processing apparatus 1 generates plasma in a state where the dielectric 120 in which the phosphor 61 is arranged is attached to the plasma processing chamber 10, and measures the plasma in the state where the phosphor 61 is arranged and the light emission of the phosphor 61 by the spectroscope 64. The controller 51 compares the measurement data obtained in the state where the phosphor 61 is not arranged with the measurement data obtained in the state where the phosphor 61 is arranged. The controller 51 measures the energy of the electrons incident on the phosphor 61 from the comparison result. By obtaining the difference between the measurement data obtained in the state where the phosphor 61 is arranged and the measurement data obtained in the state where the phosphor 61 is not arranged, the data for the light emission of the phosphor 61 may be obtained. The controller 51 obtains the difference between the measurement data obtained in the state where the phosphor 61 is arranged and the measurement data obtained in the state where the phosphor 61 is not arranged, and obtains the energy of the electrons incident on the phosphor 61. Then, the controller 51 measures the ion energy from the obtained electron energy. For example, the controller 51 stores, in the storage unit 512, the data obtained by obtaining the correspondence between the electron energy and the ion energy. The controller 51 measures the ion energy from the obtained electron energy based on the data stored in the storage unit 512.

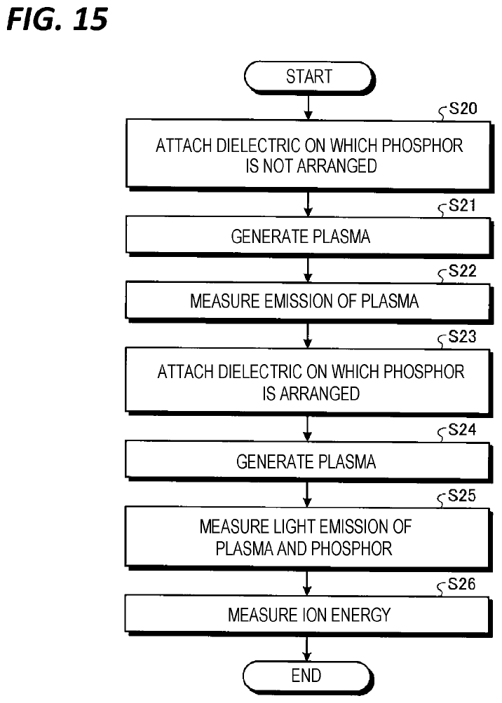

In this case, the plasma processing apparatus 1 according to the second embodiment measures plasma, for example, as follows. FIG. 15 is a flowchart illustrating an example of the flow of the plasma measuring method according to the second embodiment.

In the plasma processing apparatus 1, the dielectric 120 on which the phosphor 61 is not arranged is attached to the plasma processing chamber 10 (step S20). The dielectric 120 may be attached manually or automatically by an exchange apparatus.

The controller 51 controls each element of the plasma processing apparatus 1 to generate plasma in the plasma processing chamber 10 in a state where the phosphor 61 is not arranged inside the plasma processing chamber 10 (step S21). For example, the controller 51 controls the gas supply 20 to introduce the processing gas used for plasma generation into the plasma processing chamber 10 at a predetermined flow rate and flow rate ratio. Further, the controller 51 controls the exhaust system 40 to reduce the pressure in the plasma processing chamber 10 to a set value. Also, the controller 51 controls the RF power supply 125 to supply the radio-frequency of a predetermined power from the RF power supply 125 to the radio-frequency antenna 122. In addition, the controller 51 controls the RF power supply 30 to supply the radio-frequency power of the second RF signal of predetermined power to the lower electrode 111 from the RF generator 31b. As a result, plasma is generated in the plasma processing space 10s.

The controller 51 controls the spectroscope 64 and the drive mechanism 132, and measures the emission of plasma through the transmission window 130 by the spectroscope 64 (step S22). For example, the controller 51 moves a plurality of lenses 131 by the drive mechanism 132 to change the position of the focal point in the region where the phosphor 61 is arranged in the dielectric 120 in which the phosphor 61 is arranged, comprehensively scan the region where the phosphor 61 is arranged, and measure the light emission of the phosphor 61 by the spectroscope 64. The spectroscope 64 outputs the measurement data of the measured wavelength and emission intensity to the controller 51.

In the plasma processing apparatus 1, the phosphor 61 is arranged inside the plasma processing chamber 10 (step S23). For example, in the plasma processing apparatus 1, the dielectric 120 in which the phosphor 61 is arranged is attached to the plasma processing chamber 10. The dielectric 120 may be attached manually or automatically by an exchange apparatus.

The controller 51 controls each element of the plasma processing apparatus 1 to generate plasma in the plasma processing chamber 10 with the phosphor 61 arranged inside the plasma processing chamber 10 (step S24). The conditions for generating this plasma are preferably the same as in step S21 described above. For example, the controller 51 generates plasma with the same gas, the same pressure, the same frequency, and the same electric power as in step S21.

The controller 51 controls the spectroscope 64 and the drive mechanism 132 to measure the light emission of the plasma and the phosphor 61 through the transmission window 130 by the spectroscope 64 (step S25). For example, the controller 51 moves a plurality of lenses 131 by the drive mechanism 132 to change the position of the focal point in the region where the phosphor 61 is arranged, comprehensively scan the region where the phosphor 61 is arranged, and measure the light emission of the phosphor 61 by the spectroscope 64. The spectroscope 64 outputs the measurement data of the measured wavelength and emission intensity to the controller 51.

The controller 51 compares the measurement data obtained in the state where the phosphor 61 is not arranged and the measurement data obtained in the state where the phosphor 61 is arranged, measures the ion energy from the comparison result (step S26), and ends the process. For example, the controller 51 obtains the data of the light emission of the phosphor 61 for each position in the region where the phosphor 61 is arranged from the difference between the measurement data in the state where the phosphor 61 is arranged and the measurement data in the state where the phosphor 61 is not arranged, which is measured at the same position for each position in the region where the phosphor 61 is arranged. The controller 51 obtains the energy of the electrons incident on the phosphor 61 for each position in the region where the phosphor 61 is arranged from the obtained data. The controller 51 measures the ion energy from the obtained electron energy.

As described above, the plasma processing apparatus 1 according to the embodiment includes a plasma processing chamber 10, a support portion 11 (stage), an RF power supply 125 (plasma generation source), a transmission window 130, a phosphor 61, a spectroscope 64, and a controller 51. The support portion 11 is provided in the plasma processing chamber 10. The RF power supply 125 generates plasma in the plasma processing chamber 10. The transmission window 130 is provided in the plasma processing chamber 10 and transmits light. The phosphor 61 is arranged in the plasma processing chamber 10 and emits light according to the energy of incident electrons. The spectroscope 64 is arranged outside the plasma processing chamber 10 and measures the light emission from the phosphor 61 through the transmission window 130. The controller 51 measures the ion energy from the measurement result of the spectroscope 64. As a result, the plasma processing apparatus 1 may measure the ion energy of the plasma processing.

Further, the transmission window 130 is provided on the side wall of the plasma processing chamber 10. The phosphor 61 is arranged on the upper surface in the plasma processing chamber 10. The plasma processing apparatus 1 further includes a lens 131. The lens 131 is arranged between the transmission window 130 and the spectroscope 64, and focuses on a part of the region where the phosphor 61 is arranged. As a result, the plasma processing apparatus 1 may measure the ion energy in the region focused by the lens 131.

Further, the plasma processing apparatus 1 further includes a drive mechanism 132. The drive mechanism 132 drives either or both of the lens 131 and the spectroscope 64 so that the position of the focal point moves within the region where the phosphor 61 is arranged. As a result, the plasma processing apparatus 1 may measure the ion energy at various positions by moving the position of the focused region of the lens 131 by the drive mechanism 132.

Although the embodiments have been described above, the embodiments disclosed this time need to be considered as illustrative in all points and not restrictive. Indeed, the embodiments described above may be embodied in a variety of forms. The embodiments described above may be omitted, substituted, or changed in various forms without departing from the scope of the appended claims and the subject matter thereof.

For example, in the second embodiment described above, descriptions have been made on a case where the position of the focal point is moved by driving either or both of the lens 131 and the spectroscope 64 by the drive mechanism 132. However, the present disclosure is not limited thereto. Any configuration may be used as long as the position of the focal point may be moved. For example, the position of the focal point may be moved by driving an optical component such as a lens or a mirror. Further, for example, a plurality of lenses may be arranged so as to have different optical axes, and the light collected by the plurality of lenses may be supplied to the spectroscope 64 via an optical fiber for scanning.

The technique of the present disclosure may be adopted in any plasma processing apparatus. For example, the plasma processing apparatus 1 may be any type of plasma processing apparatus, such as a plasma processing apparatus that excites a gas by a surface wave such as a microwave.

Further, in the above-described embodiment, the plasma etching processing apparatus 1 has been described as an example, but the disclosed technique is not limited thereto. The disclosed technology may also be applied to a film forming apparatus using plasma, a reforming apparatus, and the like.

Further, in the above-described embodiment, the case where the substrate is a semiconductor wafer has been described as an example, but the present invention is not limited thereto. The substrate may be another substrate such as a glass substrate.

According to the present disclosure, the ion energy of plasma processing may be measured.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma measuring apparatus comprising:
a chamber;
a stage provided in the chamber;
a plasma generation source configured to generate plasma in the chamber;
a transmission window provided in the chamber and configured to transmit light;
a phosphor arranged in the chamber and configured to emit light according to energy of incident electrons;
a spectroscope arranged outside the chamber and configured to measure light emission from the phosphor through the transmission window; and
a controller configured to measure an ion energy from measurement results by the spectroscope.

2. The plasma measuring apparatus according to claim 1, wherein the phosphor is arranged in an upper portion of the chamber.

3. The plasma measuring apparatus according to claim 1, wherein the phosphor includes a plurality of types of phosphors that emits light at different wavelengths due to incidence of electrons having different energies.

4. The plasma measuring apparatus according to claim 3, wherein the phosphor is arranged so that adjacent phosphors are of different types.

5. The plasma measuring apparatus according to claim 1, further comprising:
an upper electrode that faces the stage,
wherein the transmission window is provided in a center of the upper electrode, and
the phosphor is arranged on a surface of the transmission window facing the stage.

6. The plasma measuring apparatus according to claim 1,
wherein the transmission window is provided on a side wall of the chamber, and the phosphor is arranged on an upper surface in the chamber, and
a lens is arranged between the transmission window and the spectroscope to focus on a portion of a region where the phosphor is arranged.

7. The plasma measuring apparatus according to claim 6, further comprising:
a driver configured to drive either or both of the lens and the spectroscope so that a position of a focal point moves within the region where the phosphor is arranged.

8. The plasma measuring apparatus according to claim 1, wherein the phosphor is any of Zn₃(PO₄)₂:Mn, Zn₂SiO₄:Mn, ZnS:Ag, ZnCdS:Ag, ZnS:Au, ZnS:Cu, ZnS:Al, YVO₄:Eu, Y₂O₃:Eu, and Y₂O₂S:Eu.

9. The plasma measuring apparatus according to claim 1, wherein the phosphor is covered with a metal thin film.

10. A plasma measuring method comprising:
generating plasma in a chamber including a phosphor that emits light according to energy of incident electrons and a transmission window that transmits light;
measuring light emission from the phosphor through the transmission window by a spectroscope arranged outside the chamber; and
measuring the energy of electrons incident on the phosphor from the measurement result.

11. The plasma measuring method according to claim 10, further comprising:
arranging the phosphor detachably inside the chamber,
wherein the generating of the plasma includes generating a first plasma in the chamber in a state where the phosphor is not arranged inside the chamber, and generating a second plasma in the chamber in a state where the phosphor is arranged inside the chamber,
the measuring of the light emission includes measuring light emission from the phosphor through the transmission window when the first plasma is generated, and measuring light emission from the phosphor through the transmission window when the second plasma is generated, and
the measuring of the energy of the electrons includes comparing first data measured when the first plasma is generated with second data measured when the second plasma is generated, and measuring the energy of electrons incident on the phosphor based on a result of the comparing.

12. The plasma measuring method according to claim 11, wherein in the arranging of the phosphor, a member not provided with the phosphor and a member provided with the phosphor are exchanged with each other inside the chamber.

13. The plasma measuring method according to claim 10, wherein the generating of plasma and the measuring of light emission are performed in a state where a substrate is placed on a stage arranged inside the chamber.

14. The plasma measuring method according to claim 11, wherein the first plasma and the second plasma are generated by a same type of gas.

15. The plasma measuring method according to claim 11, wherein in the measuring of the light emission, either or both of the spectroscope and the lens that is arranged between the transmission window and the spectroscope and focuses on a portion of the region where the phosphor is arranged are driven by a drive mechanism so that a position of a focal point moves within the region where the phosphor is arranged, and the light emission from the phosphor is measured when the first plasma is generated and when the second plasma is generated, respectively, and
in the measuring of the energy of the electrons, the first data and the second plasma measured at a same position in the region where the phosphor is arranged are compared with each other, and the energy of the electrons incident at each position is measured from a result of the comparison.
